(19) United States
(12) Patent Application Publication
(10) Pub. No.: US 2002/0060345 A1
(43) Pub. Date: May 23, 2002

(54) Esd protection circuit triggered by low voltage

(75) Inventors: Ta-Lee Yu, Hsinchu Hsien (TW); Shi-Tron Lin, Taipei (TW)

Correspondence Address: Richard P. Berg. Esq, c/o LADAS & PARRY, Suite 2100, 5670 Wilshire Boulevard, Los Angeles, CA, 90036-5679, US

(73) Assignee: Winbond Electronics Corp.

(21) Appl. No.: 09/992,416

(22) Filed: Nov. 16, 2001

(30) Foreign Application Priority Data
Nov. 20, 2000 (TW) 89124513

(51) Int. Cl. H01L 29/76

(52) U.S. Cl. 257/371

(57) ABSTRACT

The present invention provides a low-voltage-triggered electrostatic discharge (LVTESD) protection circuit coupled to a pad of an integrated circuit (IC) to protect core circuits of the IC from ESD. The ESD protection circuit comprises a semiconductor substrate having the first conductivity type, a well region having the second conductivity type is formed in the semiconductor substrate, and an anode-doped region having the first conductivity type and formed in the well region to become an anode of a semiconductor control rectifier (SCR). A gate structure is formed in the semiconductor substrate outside the well region. A first doped region having the second conductivity type is formed between the well region and the gate structure in the semiconductor substrate. A second doped region having the second conductivity type is formed adjacent to the second side of the gate structure in the semiconductor substrate. A plurality of isolated islands are evenly formed and distributed in the first doped region so that current in the first doped region must flow around the isolated islands to increase the resistance of the first doped region.

### BACKGROUND OF THE INVENTION

1. Field of the Invention

The present invention relates in general to a electrostatic discharge (ESD) protection circuit triggered by low voltage. Particularly, the present invention relates to an ESD protection circuit comprising a durable metal oxide semiconductor (MOS).

2. Description of the Related Art

ESD is a major concern for estimating the reliability of an integrated circuit (IC). All components of the IC having external connections, such as input pins, output pins, I/O pins, and power-bus pins must have the capability to discharge ESD stress and protect the core circuit of the IC.

Referring to FIG. 1, the conventional ESD protection circuit in U.S. Pat. No. 5,456,189 uses a lateral semiconductor control rectifier (LSCR) and a MOS transistor to achieve ESD protection. As shown in FIG. 1, the ESD protection circuit comprises a p-substrate 16, an N-well 18, a p-type doped region 20 in the N-well 18 as an anode, and an NMOS 22. The NMOS 22 comprises a gate 26, an n-type second doped region 30 and an n-type first doped region 28. The anode 20, the N-well 18, the P-substrate 16 and the second doped region 30 form the LSCR. The first doped region 28 is formed at the junction between the N-well 18 and the P-substrate 16 to dissipate the current in the N-well 18. A p+ first contact region 34 and an n+ second contact region 36 are respectively formed in the P-substrate 16 and the N-well 18 as shown in FIG. 1. The second contact region 36 and the anode 20 are both coupled to a pad 12, then coupled to a core circuit. The gate 26 of the MOS 22 and the first contact region 34 are coupled to a power pad, such as Vss.

When ESD stress occurs at the pad 12, the major voltage drop occurs at the junction between the N-well 18 and the P-substrate 16. Due to the difference of doped concentration between the N-well 18 and the P-substrate 16, an avalanche breakdown voltage is lowest at the junction thereof to allow the current to dissipate into the substrate 16, triggering the 10 LSCR. The ESD stress is discharged through the LSCR and thus the core circuit is protected.

The resistance of the source and drain of the MOS have reduced with the development of the self-aligned-silicide (Salicide) process. A large voltage drop occurs between the first doped region 28 and the gate 26 because of the smaller resistance of the first doped region 28. The gate oxide under the gate 26 is designed to tolerate only low voltages (about 3V) under normal conditions, not the high voltage stress resulting here. A conventional solution is to have the salicide process performed at the core circuit, but not at the ESD protection circuit. By doing so, a photo mask, creating extra manufacturing costs, is needed.

Another solution is to increase the resistance of the first doped region 28 by increasing the length of the first doped region 28. Unfortunately, additional increases in manufacturing costs also result from the increased area of the first doped region 28. Worst of all, the resistance between the first doped region 28 and the MOS is not evenly distributed, causing uneven loading on the MOS gate which then damages the gate oxide of the gate 26.

### SUMMARY OF THE INVENTION

An object of the present invention is to provide an ESD protection circuit comprising a durable MOS transistor. The first doped region of the MOS transistor is specially designed to have higher resistance without changing the manufacturing process. Furthermore, the current load on the MOS gate is equally distributed to prevent damage to the gate oxide layer of the MOS gate in an ESD event.

The present invention provides a low-voltage-triggered electrostatic discharge (LVTESD) protection circuit coupled to a pad of an integrated circuit (IC) to protect core circuits of the IC from ESD event. The ESD protection circuit comprises a semiconductor substrate having the first conductivity type, a well region having the second conductivity type formed in the semiconductor substrate, and an anode-doped region having the first conductivity type formed in the well region to become an anode of a semiconductor control rectifier (SCR). The MOS transistor has a gate structure in the semiconductor substrate outside the well region. The gate structure has a first side and a second side. A first doped region having the second conductivity type is formed between the well region and the gate structure immediately adjacent to the first side of the gate structure in the semiconductor substrate. A second doped region having the second conductivity type is formed next to the second side of the gate structure in the semiconductor substrate. A plurality of isolated islands are formed and distributed in the first doped region so that a current flow in the first doped region has to go around the isolated islands and the resistance of the first doped region is increased.

With reference to circuit design, the present invention provides another low-voltage-triggered electrostatic discharge (LVTESD) protection circuit, coupled to a pad of an integrated circuit (IC) to protect the core circuit of the IC from ESD stress. The LVTESD protection circuit comprises a semiconductor control rectifier (SCR) and a metal oxide semiconductor (MOS). The SCR comprises an anode, a anode gate, a cathode and a cathode gate. The anode is coupled to the pad. The MOS transistor has a second conductivity type and is formed on a semiconductor substrate having a first conductivity type comprising a well having the second conductivity type. The MOS transistor comprises a gate structure, a first doped region and second doped region.

The gate structure is formed on the semiconductor substrate and has a first side and a second side. The first doped region is formed in the semiconductor substrate between the well and the gate structure and is immediately adjacent to the first side of the gate structure. The gate structure comprises at least one contact region coupled to the anode gate. The second doped region is formed in the semiconductor substrate adjacent to the second side of the gate structure, and is coupled to the cathode. A plurality of isolated islands is formed between the contact region and the first side of the gate structure in the first doped region. Current in the first doped region must flow around the isolated islands, increasing the resistance of the first doped region.

The isolated islands can be formed in various ways, mainly to make the current in the first doped region flow around the isolated islands and increase the length of the current path. A field oxide, or a floating gate with an oxide layer and a polysilicon layer, is used to form the isolated islands in the present invention. It is well known that a field oxide can be formed by LOCOS isolation process or by a trench isolation process. Preferably, each of the isolated islands has an elongated profile and is approximately parallel or perpendicular to the first side of the gate structure so that the resistance in the first doped region is increased.

The advantage of the present invention lies in the increased resistance of the first doped region without any change made in the manufacturing process, while the current load received by the MOS gate is distributed to protect the gate oxide of the MOS transistor from ESD stress.

### BRIEF DESCRIPTION OF THE DRAWINGS

The present invention can be more fully understood by reading the subsequent detailed description in conjunction with the examples and references made to the accompanying drawings, wherein:

FIG. 1 is a perspective diagram of a conventional ESD protection circuit;

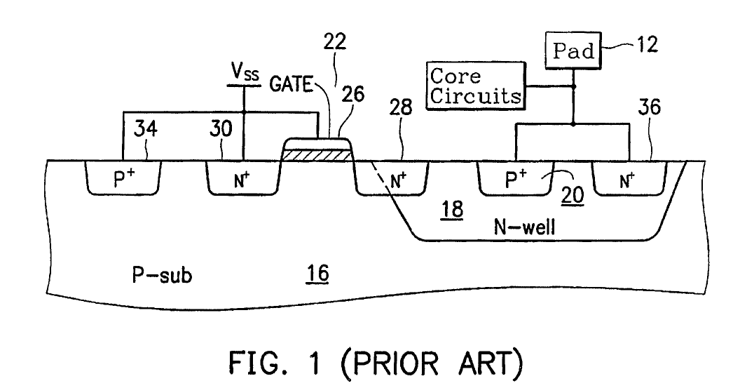

FIG. 2A is a cross section of the ESD protection circuit of the present invention;

FIG. 2B is a top view of FIG. 2A;

FIG. 2C shows the equivalent circuit diagram of FIG. 2A; and

FIG. 3 shows a cross section of the ESD protection circuit of the other embodiment of the present invention.

### DETAILED DESCRIPTION OF THE PREFERRED EMBODIMENT

The ESD protection circuit of the present invention comprises a durable MOS transistor. A first doped region of the second conductivity type of the MOS transistor is specially designed with higher resistance to protect the gate oxide of the MOS from an ESD event.

As an example of the present invention, the first conductivity type is a p type and the second conductivity type is an n type in the present embodiment. It is apparent to those in the art that the polarity may be exchanged.

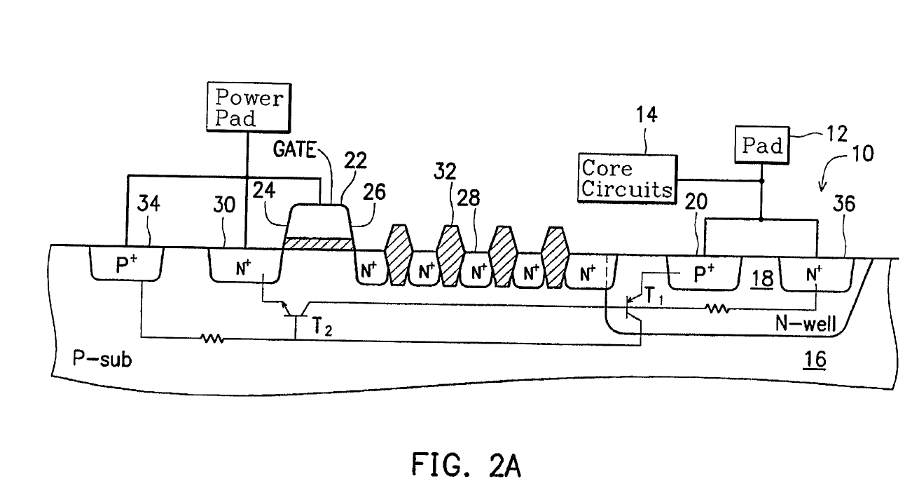

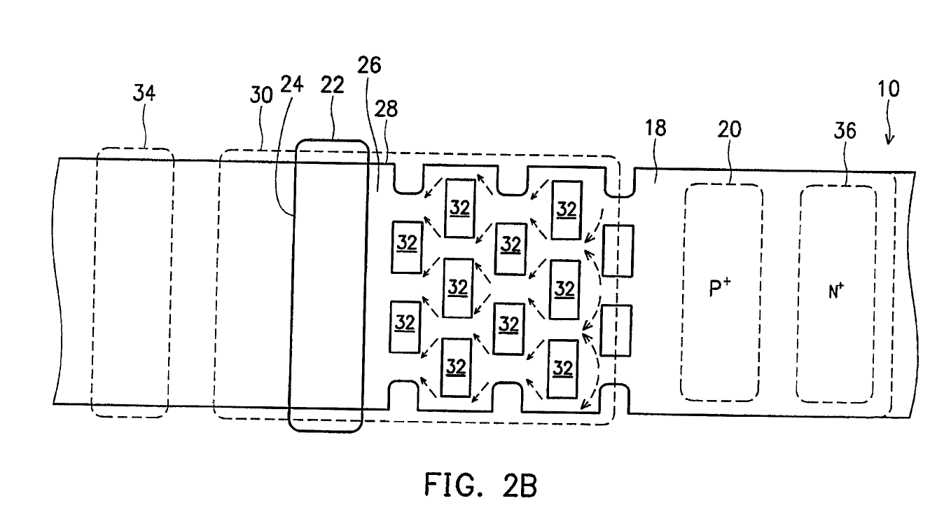

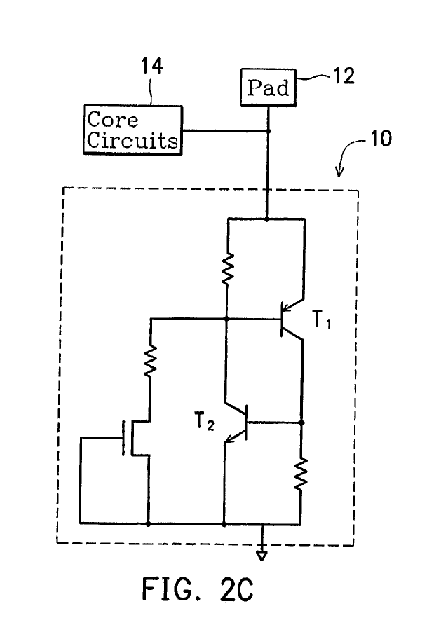

FIG. 2A is a cross section of the ESD protection circuit of the present invention, and FIGS. 2B and 2C are respectively the top view and the equivalent circuit diagram of FIG. 2A. The ESD protection circuit 10 of the present invention is coupled to a pad 12 of an integrated circuit (IC) to protect the core circuit 14 of the IC from ESD event. The ESD protection circuit 10 comprises a p-type semiconductor substrate 16, an n-well 18 and a p-type anode doped region 20. The n-well 18 is formed in the semiconductor substrate 16. The anode doped region 20 is formed in the n-well 18. A gate structure 22 is formed in the substrate 16 outside the n-well 18 and is comprised of a first side 26 and a second side 24. An n-type first doped region 28 is formed between the n-well 18 and the gate structure 22 and is adjacent to the first side 26 of the gate structure 22 in the semiconductor substrate 16. An n-type second doped region 30 is formed in the semiconductor substrate 16 and adjacent to the second side 24 of the gate structure 22 in the semiconductor substrate 16. A p-type first contact region 34 and an n-type second contact region 36 are respectively formed in the semiconductor substrate 16 and the n-well 18. As shown in FIG. 2A, the anode doped region 20, the n-well 18, the semiconductor substrate 16 and the second doped region 30 form a PNPN structure. Therefore, the anode doped region 20, the n-well 18, the semiconductor substrate 16 and the second doped region 30 are respectively the anode, anode gate, cathode gate and cathode of a semiconductor control rectifier (SCR) formed by the PNPN structure.

A plurality of isolated islands of field oxide layers 32 with approximately the same width are evenly formed and distributed in the first doped region 28 as shown in FIGS. 2A and 2B. When a current flows through the first doped region 28, the current does not pass through the field oxide layers 32, but around them, so that the resistance of the first doped region 28 is increased.

The first contact region 34, the second doped region 30 and the gate of the gate structure 22 are coupled to a power pad, such as VSS. The first doped region 28 functions as a resistor due to the result of the field oxide 32 layers. One end of the resistor is coupled to the gate structure 22, and the other end is coupled to the n-well 18, the anode gate. The second contact region 36 and the anode doped region 20 are coupled to the pad 12 (the anode). The equivalent circuit diagram of the electronic connection is shown in FIG. 2C. When electrostatic voltage occurs at the pad 12, the voltage is transmitted to a side of the gate structure 22 slowly due to the obstruction of the isolated islands 32 in the first doped region 28. Therefore, it is possible to trigger the SCR before the voltage of the gate structure side 22 exceeds a critical value damaging the gate oxide by adjusting the resistance formed by the isolated islands 32. The gate oxide of the gate structure 22 is thus protected with the side voltage of the gate structure being reduced.

The isolated islands are distributed in the first doped region 28 to divert the current flow in the first doped region 28 and allow it to evenly reach the side of the gate structure 22. The gate structure 22 then uniformly triggers the SCR to achieve optimum ESD protection.

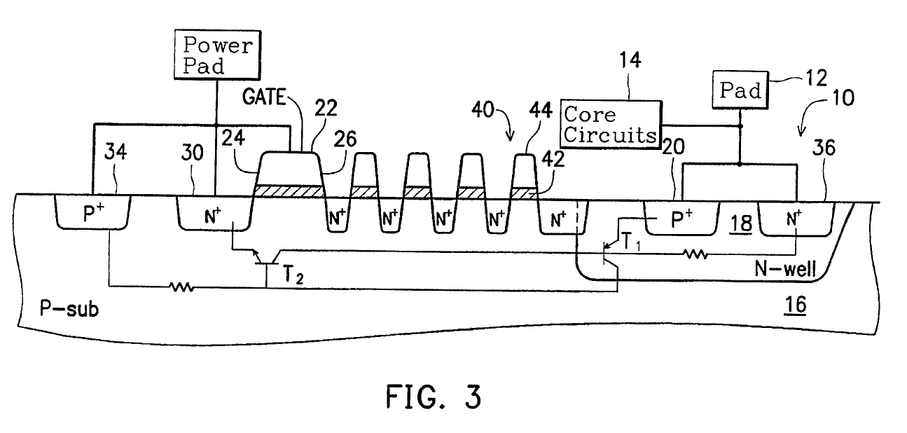

The isolated islands are primarily used to divert at least a portion of the current flow. Alternatively, a floating gate 40 can be used to replace each of the isolated islands, as shown in FIG. 3. The floating gate 40 comprises an oxide layer formed on the semiconductor substrate 16 and a polysilicon layer 44 formed on the oxide layer. Gate patterning is tight in the design rule of semiconductor process. Therefore, an increased number of tinier isolated islands are fabricated and larger resistance in the first doped region 28 results. It is noted that an isolated island can be of an elongated shape which can be approximately parallel or perpendicular to the first side of the gate structure so that the length of the current path is increased and the resistance in the drain doped region 28 becomes higher.

In comparison to the conventional LVTESD circuit in a salicide process of semiconductor manufacturing, the present invention provides a plurality of isolated islands to increase the resistance of the drain doped region of an MOS. As a result, no extra photo mask is needed. It is noted that since the isolated islands can be fabricated thin and long and configured approximately parallel or perpendicular to the first side of the gate structure 22, not much area is needed to accommodate the isolated islands. The configuration of isolated islands helps the gate structure 22 trigger the SCR of the semiconductor evenly and achieve better performance.

Finally, while the invention has been described by way of example and in terms of the preferred embodiment, it is to be understood that the invention is not limited to the disclosed embodiments. On the contrary, it is intended to cover various modifications and similar arrangements as would be apparent to those skilled in the art. Therefore, the scope of the appended claims should be accorded the broadest interpretation so as to encompass all such modifications and similar arrangements.

What is claimed is:

1. A low-voltage-triggered electrostatic discharge (LVTESD) protection circuit, coupled to a pad of an integrated circuit (IC) to protect core circuits of the IC from ESD event, the ESD protection circuit comprising:
a semiconductor substrate having the first conductivity type;
an well region having the second conductivity type, formed in the semiconductor substrate;
an anode doped region having the first conductivity type, formed in the well region;
a gate structure, formed in the semiconductor substrate and outside the well region, the gate structure having a first side and a second side;
a first doped region having the second conductivity type, formed between the well region and the gate structure, immediately adjacent to the first side of the gate structure in the semiconductor substrate;
a second doped region having the second conductivity type, formed next to the second side of the gate structure in the semiconductor substrate; and
a plurality of isolated islands distributed in the first doped region so that the resistance of the first doped region is increased.

2. The ESD protection circuit in claim 1, wherein the ESD protection circuit further comprises:
a first contact region having the first conductivity type, formed in the semiconductor substrate; and
a second contact region having the second conductivity type, formed in the well region;
wherein the first contact region is coupled to the second doped region and a power pad of the IC, and the anode doped region is coupled to the pad.

3. The ESD protection circuit in claim 1, wherein the second contact region is coupled to the anode doped region.

4. The ESD protection circuit in claim 1, wherein the gate structure has an oxide layer formed on the semiconductor substrate, and a polysilicon layer formed on the oxide layer.

5. The ESD protection circuit in claim 4, wherein the polysilicon layer is coupled to the second doped region.

6. The ESD protection circuit in claim 1, wherein each of the isolated islands comprises an oxide layer formed on the semiconductor substrate, and a polysioicon layer formed on the oxide layer.

7. The ESD protection circuit in claim 1, wherein the isolated islands are field oxide.

8. The ESD protection circuit in claim 1, wherein each of the isolated islands has approximately the same width.

9. The ESD protection circuit of claim 1, wherein each of the isolated islands is elongated and approximately parallel to the first side of the gate structure.

10. The ESD protection circuit of claim 1, wherein each of the isolated islands is elongated and approximately perpendicular to the first side of the gate structure.

11. THE ESD protection circuit in claim 1, wherein the first type is a P-type, and the second conductivity type is an n-type.

12. A low-voltage-triggered electrostatic discharge (LVTESD) protection circuit, coupled to a pad of an integrated circuit (IC) to protect the core circuit of the IC from ESD stress, the LVTESD protection circuit comprising:
a semiconductor control rectifier, comprising an anode, a anode gate, a cathode and a cathode gate, the anode is coupled to the pad; and
a metal-oxide-semiconductor (MOS) having a second conductivity type, formed on a semiconductor substrate having a first conductivity type comprising a well having the second conductivity type, the MOS comprising:
a gate structure, formed on the semiconductor substrate, having a first side and a second side;
a first doped region, formed in the semiconductor substrate between the well and the gate structure and immediately adjacent to the first side of the gate structure, comprising at least one contact region coupled to the anode gate;
a second doped region, formed in the semiconductor substrate adjacent to the second side of the gate structure, and coupled to the cathode; and
a plurality of isolated islands, formed between the contact region and the first side of the gate structure in the first doped region, resulting in increased resistance of the first doped region.

13. The ESD protection circuit in claim 12, wherein each of the isolated islands comprises an oxide layer on the semiconductor substrate, and a polysilicon layer on the oxide layer.

14. The ESD protection circuit in claim 12, wherein the IC further comprises a plurality of oxide layers, and each of the isolated islands is formed by one of the oxide layers.

15. The ESD protection circuit in claim 12, wherein each of the isolated islands has approximately the same length.

16. The ESD protection circuit in claim 12, wherein each of the isolated islands has an elongated profile and is approximately parallel to the first side of the gate structure.

17. The ESD protection circuit in claim 12, wherein each of the isolated islands has an elongated profile and is approximately perpendicular to the first side of the gate structure.

18. The ESD protection circuit in claim 12, wherein the first conductivity type is a p type, and the second conductivity type is an n type.
